(19) United States
(12) Patent Application Publication
(10) Pub. No.: US 2025/0277842 A1
(43) Pub. Date: Sep. 4, 2025

(54) INSULATION DETECTION APPARATUS AND METHOD, AND ENERGY STORAGE APPARATUS

(71) Applicant: Delta Electronics (Shanghai) CO., LTD., Shanghai (CN)

(72) Inventors: Jianxing DONG, Shanghai (CN); Lei CHEN, Shanghai (CN); Teng LIU, Shanghai (CN)

(73) Assignee: Delta Electronics (Shanghai) CO., LTD., Shanghai (CN)

(21) Appl. No.: 19/021,225

(22) Filed: Jan. 15, 2025

(30) Foreign Application Priority Data
Mar. 1, 2024 (CN) 2024102395381

(51) Int. Cl. G01R 31/12; G01R 31/16; H01M 10/42

(52) U.S. Cl. CPC G01R 31/1263; G01R 31/16; H01M 10/4285

(57) ABSTRACT

The present disclosure provides an insulation detection apparatus and method, and an energy storage apparatus, and relates to the technical field of energy storage safety. The insulation detection apparatus includes: a coupling conductor and a signal acquisition unit, where the coupling conductor and the signal acquisition unit are electrically connected, the coupling conductor and the signal acquisition unit are used to form an insulation detection loop with a device under test, and the signal acquisition unit is further used to detect an electrical signal in the insulation detection loop. The coupling plate and signal acquisition unit used in the present disclosure have a simple structure and low cost. Compared with the existing insulation impedance detection, the present disclosure has a high detection sensitivity and more reliable detection result.

### CROSS REFERENCE

This application is based upon and claims priority to Chinese Patent Application No. 2024102395381, filed on Mar. 1, 2024, the entire contents thereof are incorporated herein by reference.

### TECHNICAL FIELD

The present disclosure relates to the technical field of energy storage safety, and particularly, to an insulation detection apparatus and method, and an energy storage apparatus.

### BACKGROUND

The field of energy storage has been developing rapidly in recent years. With the rapid growth of the installed capacity of energy storage, the reports of explosion and fire accidents in energy storage power plants has become more frequent. These incidents involving energy storage have resulted in direct property losses exceeding 100 million yuan and have led to associated casualties. Consequently, the safety of energy storage systems cannot be ignored.

Most explosion and fire accidents in energy storage systems start from insulation failure, and thus it is particularly important to detect the insulation state. In the current energy storage field, the insulation impedance detection technology is widely used, but the insulation impedance detection apparatuses are usually complex in structure and control, and are costly. Meanwhile, the insulation impedance reflects the overall average state of the insulation system, and has a low sensitivity for detecting some non-penetrating concentrated insulation defects. Although the test value of the insulation impedance is still relatively high in this case, the remaining effective insulation part can no longer meet the withstand voltage requirement. In other words, it is not reliable to judge the insulation state of the system only by measuring the insulation impedance. Therefore, how to achieve insulation state detection with a high sensitivity, a high reliability and a low cost is a problem that needs to be solved urgently.

It should be noted that the information disclosed in the above background is only used to enhance an understanding of the background of the present disclosure, therefore it may include information that does not constitute the prior art known to those skilled in the art.

### SUMMARY

The present disclosure provides an insulation detection apparatus and method, and an energy storage apparatus, which at least to a certain extent overcome the problems of high cost and unreliability of insulation detection.

Other features and advantages of the present disclosure will become apparent through the following detailed description, or, may be learned partially by practice of the present disclosure.

According to an aspect of the present disclosure, an insulation detection apparatus is provided, where the apparatus includes: a coupling conductor and a signal acquisition unit, where the coupling conductor and the signal acquisition unit are electrically connected, the coupling conductor and the signal acquisition unit are used to form an insulation detection loop with a device under test, and the signal acquisition unit is further used to detect an electrical signal in the insulation detection loop.

According to another aspect of the present disclosure, an energy storage apparatus is further provided, including: an insulation detection apparatus, including: a coupling conductor and a signal acquisition unit, where the coupling conductor and the signal acquisition unit are electrically connected, the coupling conductor and the signal acquisition unit are configured to form an insulation detection loop with a device under test, and the signal acquisition unit is further configured to detect an electrical signal in the insulation detection loop; an energy storage unit and a mounting structure, where the energy storage unit and the mounting structure serve as the device under test; and the energy storage unit or the mounting structure is used to be electrically connected to the insulation detection apparatus.

According to another aspect of the present disclosure, an insulation detection method is further provided, including: providing an insulating medium between a first conductor and a second conductor; providing a coupling conductor between the first conductor and the second conductor; the first conductor, the insulating medium provided between the first conductor and the second conductor, and the second conductor constitute a first parasitic capacitor; the first conductor, the insulating medium provided between the first conductor and the coupling conductor, and the coupling conductor constitute a second parasitic capacitor; one of the first parasitic capacitor and the second parasitic capacitor is a test capacitor, and the other is a coupling capacitor; electrically connecting a signal acquisition unit between the coupling conductor and the second conductor; constituting an insulation detection loop by the signal acquisition unit, the test capacitor and the coupling capacitor; and acquiring a high-frequency pulse current signal flowing through the insulation detection loop by the signal acquisition unit, and outputting an insulation detection result of the test capacitor

The insulation detection apparatus, method and energy storage apparatus provided in the embodiments of the present disclosure include: a coupling conductor and a signal acquisition unit, where the coupling conductor and the signal acquisition unit are electrically connected, the coupling conductor and the signal acquisition unit are used to form an insulation detection loop with a device under test, and the signal acquisition unit is used to detect an electrical signal in the insulation detection loop. The present disclosure utilizes a method of partial discharge detection, forms the insulation detection loop by the coupling conductor and the signal acquisition unit with the device under test, and detects an electrical signal in the insulation detection loop when partial discharge occurs in the device under test, thereby monitoring the insulation state of the device under test. The coupling conductor and the signal acquisition unit adopted in the present disclosure has a simple structure and is cost-effective. Compared with the existing insulation impedance detection, the present disclosure has a high detection sensitivity and a more reliable detection result. The weak discharge information at the initial stage of partial discharge can be detected and early warning can be provided, thereby leaving enough time for protection action of the system. The coupling conductor can be flattened in the form of a coupling plate, with a small volume for easy integration, and can effectively detect inherent defects in insulating components, deterioration of performance of insulating components due to harsh operating conditions, insulating defects caused by design/production/assembly processes, and insulation failures such as component short circuits caused by liquid leakage. The coupling conductor can be applied in fields such as battery components, electric vehicles, energy storage systems, and smart grids. At the same time, the parasitic capacitance of the device under test is divided into two by the coupling conductor instead of installing an additional capacitor component with a high insulation requirement to construct a partial discharge detection loop, which further reduces the cost of insulation detection and the volume of the insulation detection apparatus. At the same time, the present disclosure will not increase the equivalent parasitic capacitance of the system, thereby avoiding the increase of the common-mode interference current of the system, and further preventing the increase of the volume and cost of the common-mode filter.

It should be understood that the foregoing general description and the following detailed description are exemplary and explanatory only, and do not limit the present disclosure.

### BRIEF DESCRIPTION OF THE DRAWINGS

The accompanying drawings herein, which are incorporated in and constitute a part of this specification, illustrate embodiments consistent with the present disclosure and are used in conjunction with the specification to explain the principles of the present disclosure. Obviously, the drawings in the following description are only some embodiments of the present disclosure. For those of ordinary skill in the art, other drawings can also be obtained from these drawings without paying creative effort.

FIG. 1(a) and FIG. 1(b) show schematic diagrams comparing insulation impedance detection and partial discharge detection.

FIG. 2 shows a principle diagram of partial discharge detection of an insulation detection apparatus in an embodiment of the present disclosure.

FIG. 3 shows a structural diagram of the insulation detection apparatus in an embodiment of the present disclosure.

FIG. 4 shows a schematic diagram of the insulation detection apparatus applied to a device under test in an embodiment of the present disclosure.

FIG. 5 shows a schematic diagram in which a signal acquisition unit of the insulation detection apparatus is electrically connected to a second conductor in an embodiment of the present disclosure.

FIG. 6 shows an equivalent diagram of the parasitic capacitances in FIG. 5.

FIG. 7(a) shows a structural diagram of a specific application of the insulation detection apparatus in an embodiment of the present disclosure.

FIG. 7(b) shows a structural diagram of another specific application of the insulation detection apparatus in an embodiment of the present disclosure.

FIG. 8 shows a schematic diagram of an evaluation of the location where a coupling conductor is mounted in an embodiment of the present disclosure.

FIG. 9(a) shows a schematic structural diagram of a signal acquisition apparatus in an embodiment of the present disclosure.

FIG. 9(b) shows another schematic structural diagram of the signal acquisition apparatus in an embodiment of the present disclosure.

FIG. 10 shows a schematic diagram of the principle of generating common-mode interference current in an embodiment of the present disclosure.

FIG. 11 shows a structural diagram of a phase-shift differential dual sensor in an embodiment of the present disclosure.

FIG. 12 shows an equivalent diagram of the parasitic capacitance in FIG. 11.

FIG. 13 shows an application structural diagram of the phase-shift differential dual sensor in an embodiment of the present disclosure.

FIG. 14 shows a structural diagram of integrated design of the lead in an embodiment of the present disclosure.

FIG. 15 shows a structural diagram of a discrete lead design in an embodiment of the present disclosure.

FIG. 16 shows a first schematic structural diagram of an energy storage apparatus in an embodiment of the present disclosure.

FIG. 17 shows an equivalent diagram of the parasitic capacitance in FIG. 16.

FIG. 18 shows a second schematic structural diagram of the energy storage apparatus in an embodiment of the present disclosure.

FIG. 19 shows a third schematic structural diagram of the energy storage apparatus in an embodiment of the present disclosure.

FIG. 20 shows a schematic structural diagram of the device under test in an embodiment of the present disclosure.

FIG. 21 shows a side view schematic diagram in which the signal acquisition apparatus in the embodiment of the present disclosure is applied to the device under test shown in FIG. 20.

FIG. 22 shows an insulation detection method in an embodiment of the present disclosure.

### DETAILED DESCRIPTION

Exemplary embodiments will now be described more fully with reference to the accompanying drawings. Exemplary embodiments may, however, be embodied in various forms and should not be construed as limited to the examples set forth herein. Rather, these embodiments are provided so that the present disclosure will be more thorough and complete, and the ideas of the exemplary embodiments will be fully conveyed to those skilled in the art. The described features, structures, or characteristics may be combined in any suitable manner in one or more embodiments.

In addition, the accompanying drawings are only schematic illustrations of the present disclosure and are not necessarily drawn to scale. In the accompanying drawings, the same reference sign indicates the same or similar part, and repeated descriptions thereof will be omitted. Some of the block diagrams shown in the accompanying drawings are functional entities and do not necessarily correspond to physically or logically independent entities. These functional entities may be implemented in software form, or in one or more hardware modules or integrated circuits, or in different networks and/or processor apparatuses and/or microcontroller apparatuses.

Although relative terms, such as “on” and “under” are used in this specification to describe the relative relationship of one component to another identified in the drawings, these terms are used in this specification only for convenience, e.g., in accordance with the exemplary orientations described in the accompanying drawings. It should be understood that if the apparatus identified in the drawings is turned upside down, the component described as being “on” will become the component described as being “under”. When a certain structure is “on” another structure, it may mean that the certain structure is integrally formed on other structure, or that the certain structure is “directly” placed on other structure, or that the certain structure is “indirectly” placed on other structure through another structure.

The terms “one”, “a/an”, “the”, “said” and “at least one” are used to indicate the presence of one or more elements/components/etc.; the terms “including/comprising” and “having” are used in an open-ended inclusive sense to mean that there may be an additional element/component/etc. in addition to the listed elements/components/etc.; and the terms “first”, “second” and “third” etc. are used merely as markers and are not intended to limit the number or specific uses of their objects.

The term “electrically connected” as used in this specification means that it can be connected either in series or in parallel.

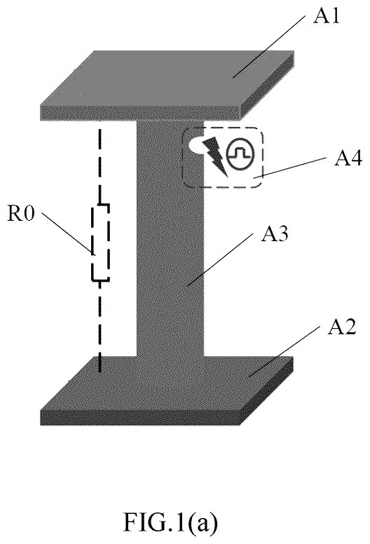

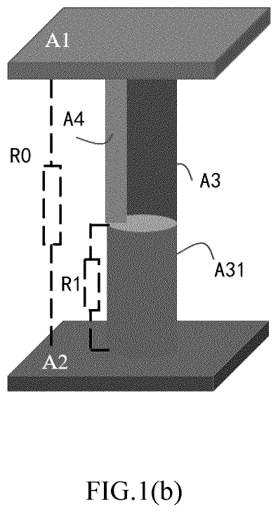

FIG. 1(a) and FIG. 1(b) show schematic diagrams comparing insulation impedance detection and partial discharge detection. As shown in FIG. 1(a), the potentials of a first conductor A1 and a second conductor A2 are different, and an insulating medium A3 exists between the first conductor A1 and the second conductor A2, which is equivalent to the existence of insulation impedance R0. In this insulation system, there is a situation as shown in FIG. 1(b): a partial concentrated insulation defect A4 has developed to such a degree that the remaining effective insulation A31 will be broken down during the withstand voltage test, but the insulation impedance value R1 measured prior to the withstand voltage test is still high. This is because these defects have not penetrated the entire insulation, and the insulation impedance detection focuses on the overall average state of the insulation system. Therefore, it is not reliable to judge the insulation state based solely on the measurement result of the insulation impedance.

At the same time, according to reports and statistics of relevant energy storage accidents, in battery energy storage systems, partial discharge phenomenon may be caused by inhomogeneous electric field, improper insulation coordination, insulation material defects, etc. The existence of partial discharge will accelerate the aging of insulating materials, increase the risk of insulation breakdown failure in the system, and even induce safety accidents such as explosions and fires. Therefore, partial discharge detection is an important detection method to evaluate the insulation state of the system.

In addition, compared with the insulation impedance detection, the partial discharge detection pays more attention to the weak points of the insulation system, has a higher detection sensitivity, and is more reliable in assessing the insulation state of the system.

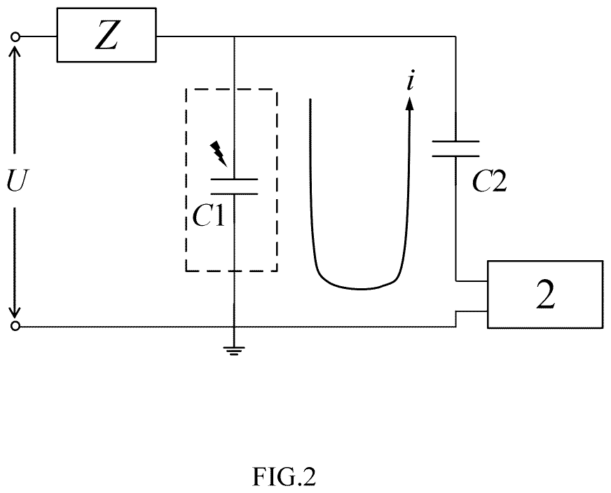

FIG. 2 shows a schematic diagram of a partial discharge detection loop in an embodiment of the present disclosure, which is a partial discharge detection using a pulse current method specified in relevant technical standards. As shown in FIG. 2, the partial discharge detection loop mainly includes: a voltage source U, a filter Z, a test sample C1 to be tested, a coupling capacitor C2 and a signal acquisition unit 2, where the voltage source U is used as an excitation source input, one end of the filter Z is connected to the voltage source U, and the other end is connected to the test sample C1, and the test sample C1 is the equivalent capacitance of the insulating component to be detected in the device under test (DUT). The coupling capacitor C2 and the signal acquisition unit 2 are connected in series and are connected in parallel with the test sample C1 to form a detection loop. The signal acquisition unit 2 collects the high-frequency pulse electrical signal generated by the test sample C1 due to partial discharge. The amplitude of the pulse electrical signal is proportional to the discharge amount. The sensitivity of partial discharge detection is positively correlated with the ratio of the coupling capacitor C2 to the equivalent capacitance of the test sample C1.

At the same time, the inventor(s) found that in order to accurately detect the partial discharge of the test sample C1, it is necessary to ensure that the connected coupling capacitor C2 does not generate partial discharge to avoid interfering with the detection result. Therefore, if partial discharge detection is performed by installing an additional capacitor device on the device under test, the additionally installed capacitor device must have a very high insulation level, and the cost of the device is high correspondingly. Moreover, the additional installation of the capacitor device will lead to the increase in the equivalent parasitic capacitance of the system, which is equivalent to the sum of the parasitic capacitance value of the device under test and the capacitance value of the additionally installed capacitor. The increase in the equivalent parasitic capacitance leads to an increase in the common-mode interference current, which results in an increase in system losses and the volume of the common-mode filter, and brings out an additional increase in system cost.

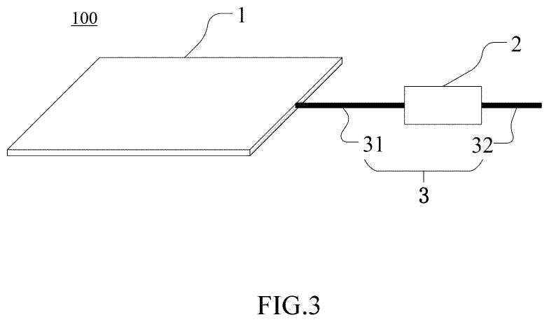

Since the coupling capacitor C2 is necessary in partial discharge detection, in order to solve the problems of increased cost and increased system interference caused by installing the additional capacitor device, the present disclosure provides an embodiment of an insulation detection apparatus. FIG. 3 shows a structural diagram of the insulation detection apparatus 100 in an embodiment of the present disclosure. As shown in FIG. 3, the insulation detection apparatus 100 includes: a coupling conductor 1 and a signal acquisition unit 2, where the coupling conductor 1 and the signal acquisition unit 2 are electrically connected, the coupling conductor 1 and the signal acquisition unit 2 are used to form an insulation detection loop with a device under test, and the signal acquisition unit 2 is further used to detect a partial discharge signal in the insulation detection loop. The coupling conductor 1 and the signal acquisition unit 2 are electrically connected via a lead 3. The “lead” referred to herein may be in various forms of conductor such as a wire, a conductor structure on a circuit board, a copper sheet, etc.

The insulation detection apparatus 100 composed of the coupling conductor 1 and the signal acquisition unit 2 has a simple structure and low cost, and has high detection sensitivity and more reliable detection results compared with the existing insulation impedance detection apparatus. It can detect the weak discharge information at the initial stage of partial discharge and issue a warning in advance, leaving sufficient time for protection action of the system. The coupling conductor 1 may be implemented in the form of coupling plate to achieve a flat structure, with a small volume for easy integration, and can effectively detect inherent defects in insulating components, deterioration of performance of insulating components due to harsh operating conditions, insulating defects generated during design/production/assembly processes, and insulation failures such as component short circuits caused by liquid leakage. At the same time, the parasitic capacitance of the device under test 4 is divided into two by the coupling conductor 1 instead of installing an additional capacitor device with high insulation requirement to construct a partial discharge detection loop, which further reduces the cost of insulation detection and the volume of the insulation detection apparatus. At the same time, the present disclosure will not increase the equivalent parasitic capacitance of the system, thereby avoiding the increase of the common-mode interference current of the system, and further preventing the increase of the volume and cost of the common-mode filter.

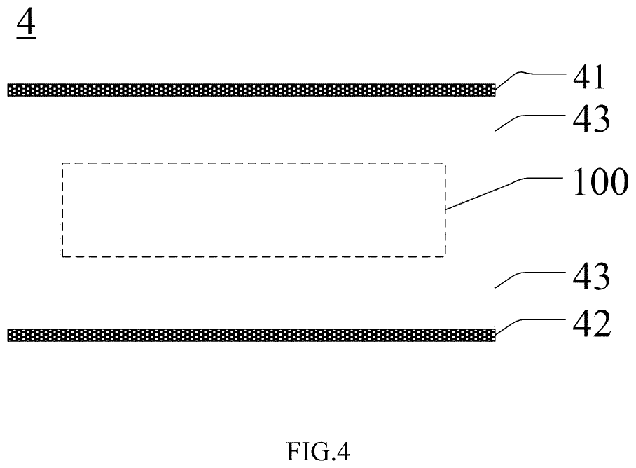

FIG. 4 shows a schematic diagram in which the insulation detection apparatus 100 is applied to the device under test 4 in an embodiment of the present disclosure. As shown in FIG. 4, the device under test 4 includes a first conductor 41 and a second conductor 42, the first conductor 41 and the second conductor 42 have different potentials, and an insulating medium 43 exists between the first conductor 41 and the second conductor 42. It should be noted that, for the sake of simplicity, FIG. 4 does not show the specific structure of the insulation detection apparatus 100. Referring to FIG. 3, it can be seen that the coupling conductor 1 is provided between the first conductor 41 and the second conductor 42, and the signal acquisition unit 2 is electrically connected to the first conductor 41 or the second conductor 42 via the lead 3 to form the insulation detection loop. The electrical signal in the insulation detection loop detected by the signal acquisition unit 2 is a partial discharge signal in the device under test 4. It should be noted that the coupling conductor 1 in the insulation detection apparatus 100 shown in FIG. 4 is provided between the first conductor 41 and the second conductor 42, one end of the signal acquisition unit 2 in the insulation detection apparatus 100 is electrically connected to the coupling conductor 1, and the other end only needs to be electrically connected to the first conductor 41 or the second conductor 42, and the position of the signal acquisition unit 2 is not limited in the present disclosure. In some embodiments of the present disclosure, the signal acquisition unit 2 may be located between the coupling conductor 1 and the second conductor 42. In some other embodiments of the present disclosure, the signal acquisition unit 2 may also be located between the coupling conductor 1 and the first conductor 41.

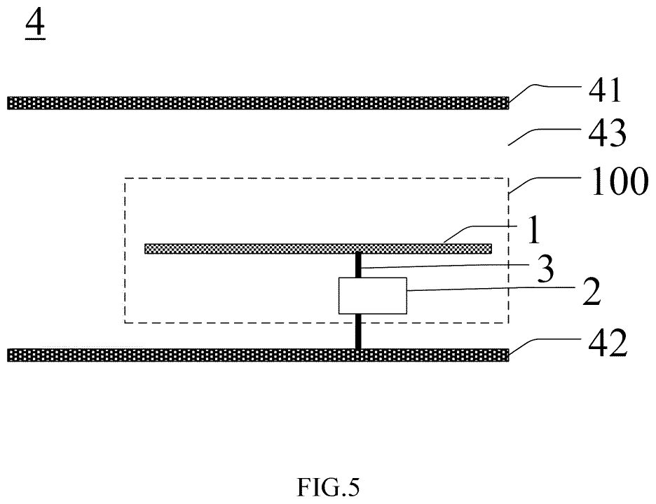

FIG. 5 shows a schematic diagram in which a signal acquisition unit 2 is electrically connected to the second conductor 42 of the insulation detection apparatus 100 in an embodiment of the present disclosure. As shown in FIG. 5, when the insulation detection apparatus 100 detects partial discharge, there are at least two conductor structures with different potentials in the device under test 4, such as the first conductor 41 and the second conductor 42 in this embodiment. The insulating medium 43 is provided between the first conductor 41 and the second conductor 42. The coupling conductor 1 is disposed in the insulating medium 43 between the first conductor 41 and the second conductor 42. The coupling conductor 1 is electrically connected to the signal acquisition unit 2 via the lead 3, and the signal acquisition unit 2 is also electrically connected to the second conductor 42 via the lead 3, thereby forming the insulation detection loop. The insulation state of the insulating medium 43 determines whether the signal acquisition unit 2 is able to collect the partial discharge signal; when the insulation state of the insulating medium 43 is normal, no partial discharge signal is generated; when the insulation state of the insulating medium 43 begins to partially fail, due to the existence of a potential difference between the first conductor 41 and the second conductor 42, discharge will occur at the partially failed position of the insulating medium 43, thereby generating a partial discharge signal. It will be appreciated that in other embodiments of the present disclosure, the signal acquisition unit 2 of the insulation detection apparatus 100 may also be electrically connected to the first conductor 41.

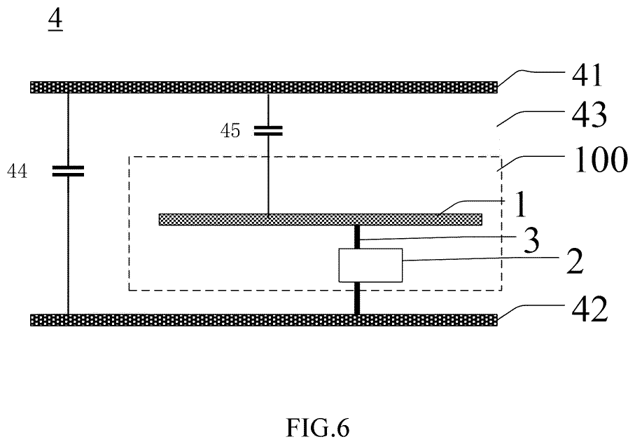

FIG. 6 shows an equivalent diagram of a parasitic capacitance in FIG. 5. As shown in FIG. 6, the first conductor 41, the insulating medium 43 provided between the first conductor 41 and the second conductor 42, and the second conductor 42 constitute a first parasitic capacitor 44; the first conductor 41, the insulating medium 43 provided between the first conductor 41 and the coupling conductor 1, and the coupling conductor 1 constitute a second parasitic capacitor 45; one of the first parasitic capacitor 44 and the second parasitic capacitor 45 is a test capacitor, and the other is a coupling capacitor; the signal acquisition unit 2 is electrically connected between the coupling conductor 1 and the second conductor 42; the signal acquisition unit 2, the test capacitor and the coupling capacitor constitute the insulation detection loop; and the signal acquisition unit 2 acquires the partial discharge signal flowing through the insulation detection loop and outputs a detection result of partial discharge of the test capacitor.

The device under test 4 itself has an equivalent parasitic capacitance, and by arranging the coupling conductor 1 between the first conductor 41 and the second conductor 42, the parasitic capacitance of the device under test 4 is divided into two, namely, the first parasitic capacitance 44 and the second parasitic capacitance 45. Since no additional capacitor device is added, but rather the original parasitic capacitance is divided into two, there is less system interference with the device under test 4. Furthermore, since the division is performed on the original parasitic capacitance, the first parasitic capacitance 44 and the second parasitic capacitance 45 are mutually the test capacitance and the coupling capacitance.

When there is partial insulation failure in the insulating medium 43 arranged between the first conductor 41 and the second conductor 42, a partial discharge occurs. At this time, the first parasitic capacitor 44 serves as the test capacitor; the second parasitic capacitor 45 serves as the coupling capacitor, and the signal acquisition unit 2 collects a pulse current signal of the partial discharge and outputs the partial discharge detection result of the test capacitor.

When there is partial insulation failure in the insulating medium 43 arranged between the first conductor 41 and the coupling conductor 1, a partial discharge occurs. At this time, the second parasitic capacitor 45 serves as the test capacitor; the first parasitic capacitor 44 serves as the coupling capacitor, and the signal acquisition unit 2 collects a pulse current signal of the partial discharge and outputs the partial discharge detection result of the test capacitor.

The manner of dividing the equivalent parasitic capacitance of the insulating medium 43 into two by using the coupling conductor 1 does not increase the parasitic capacitance, and cause less system interference to the device under test 4. The first parasitic capacitance 44 and the second parasitic capacitance 45 are mutually test capacitance and coupling capacitance, which can realize the partial discharge detection of the whole insulating medium 43. Compared with the insulation impedance detection apparatus, the method of providing the coupling conductor 1 greatly reduces the cost and has high detection sensitivity. Compared with the method of adding an additional capacitor device to achieve partial discharge detection, since there is no need to externally connect a capacitor device with high insulation requirement and the equivalent parasitic capacitance of the system is not increased, there is no need for a corresponding filter that increases the volume to filter the increased common-mode interference current, and the cost is greatly reduced.

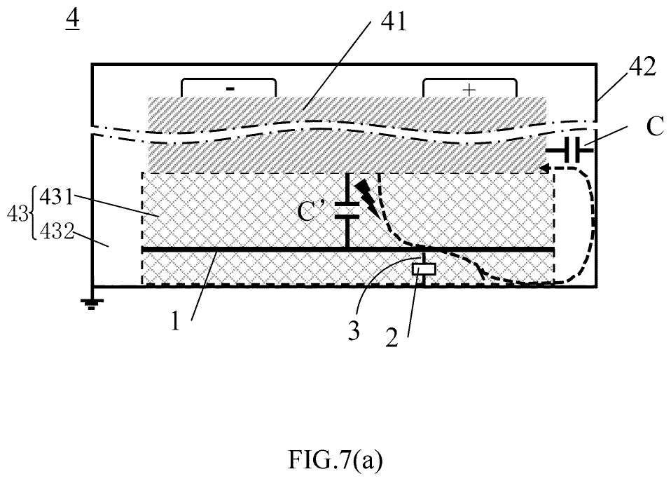

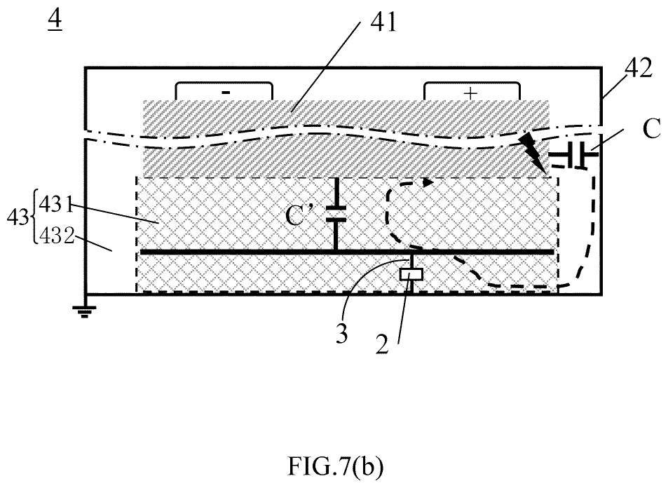

FIG. 7(a) shows a structural diagram of a specific application of the insulation detection apparatus 100 in an embodiment of the present disclosure. It should be noted that the aforementioned device under test 4, first conductor 41, second conductor 42, insulating medium 43, coupling conductor 1, etc. refer to different component names in different application scenarios, but they all refer to the insulation detection apparatus and the device under test 4 to which it is applied in the embodiments of the present disclosure. Therefore, the above components are denoted by the same reference numerals in different application scenarios.

As shown in FIG. 7(a), the device under test 4 is an energy storage battery 4, which includes: a battery cell, a battery cell aluminum shell 41, polyurethane (PU) glue 431, an insulating gas 432 and a box shell 42. The battery cell and the battery cell aluminum shell 41 are electrically connected, and thus the battery cell and the battery cell aluminum shell 41 have the same potential. Here, the battery cell aluminum shell 41 serves as the first conductor 41. The PU glue 431 serves as the insulating medium 43 to insulate and isolate the mounting surface of the battery cell aluminum shell 41 from the box shell 42, and the insulating gas 432 also serves as the insulating medium 43 to insulate and isolate the other surfaces of the battery cell aluminum shell 41 from the box shell 42. The box shell 42 is grounded as a second conductor 42, and there is a potential difference between the box shell 42 and the battery cell aluminum shell 41. The coupling plate 1 serves as a coupling conductor 1 and is arranged inside the PU glue 431 between the battery cell aluminum shell 41 and the box shell 42. The coupling plate 1 is electrically connected to one end of the signal acquisition unit 2 through a first lead 31, and the other end of the signal acquisition unit 2 is electrically connected to the box shell 42 through a second lead 32, for collecting pulse current signals of partial discharge. The battery cell aluminum shell 41, the insulating medium 43 between the battery cell aluminum shell 41 and the box shell 42, and the box shell 42 constitute a parasitic capacitor C, which is equivalent to the first parasitic capacitor 44 mentioned above. The battery cell aluminum shell 41, the insulating medium PU glue 431 between the battery cell aluminum shell 41 and the coupling plate 1, and the coupling plate 1 constitute a parasitic capacitor C′, which is equivalent to the second parasitic capacitor 45. The parasitic capacitance C and the parasitic capacitance C′ are mutually the test capacitance and the coupling capacitance, that is, when the parasitic capacitance C is the test capacitance, the parasitic capacitance C′ is the coupling capacitance, and when the parasitic capacitance C′ is the test capacitance, the parasitic capacitance C is the coupling capacitance. In the embodiment shown in FIG. 7(a), when there is a partial insulation failure in the PU glue 431 disposed between the battery cell aluminum shell 41 and the coupling plate 1, for example, a partial high field strength distortion within a bubble defect causes a partial discharge, the parasitic capacitor C′ serves as the test capacitor, the parasitic capacitor C serves as the coupling capacitor, and the signal acquisition unit 2 collects the pulse current signal of the partial discharge and outputs the partial discharge detection result of the test capacitor. Meanwhile, it should be noted that the insulating medium 43 between the battery cell aluminum shell 41 and the box shell 42 may be other insulating medium such as insulating paper, insulating film, etc. in addition to the insulating gas 432.

FIG. 7(b) shows another structural diagram of a specific application of the insulation detection apparatus in an embodiment of the present disclosure. The difference between the embodiment shown in FIG. 7(a) and the embodiment shown in FIG. 7(b) is that, in the embodiment shown in FIG. 7(b), when there is a partial insulation failure in the insulating medium 43 disposed between the battery cell aluminum shell 41 and the box shell 42, partial discharge occurs, and at this time, the parasitic capacitor C serves as the test capacitor, the parasitic capacitor C′ serves as the coupling capacitor, and the signal acquisition unit 2 collects the pulse current signal of the partial discharge and outputs the partial discharge detection result of the test capacitor. The remaining features are the same as those of the embodiment shown in FIG. 7(a) and will not be described in detail herein. Meanwhile, it should be noted that the insulating medium 43 between the battery cell aluminum shell 41 and the box shell 42 may be other insulating medium such as insulating paper, insulating film, etc. in addition to the insulating gas 432.

By providing the coupling plate 1, the original parasitic capacitance of the energy storage battery 4 is divided into two, and partial discharge detection is realized without increasing the equivalent parasitic capacitance of the system, thereby reducing the interference to the system where the energy storage battery 4 is located. Furthermore, since the increase of common-mode interference current is prevented, there is no need for a corresponding filter that increases the volume to filter the increased common-mode interference current, which further reduces the volume of the system of the insulation detection apparatus 100 and the energy storage battery 4, and reduces the cost of insulation detection.

Since the first parasitic capacitance 44 and the second parasitic capacitance 45 are mutually the test capacitance and the coupling capacitance, the ratio of the coupling capacitance to the test capacitance is positively correlated with the sensitivity of partial discharge detection. The ratio of the coupling capacitance to the test capacitance may be adjusted by adjusting the position of the coupling conductor 1 in the insulating medium 43. When the capacitance value of the first parasitic capacitor 44 is equal to the capacitance value of the second parasitic capacitor 45, the sensitivity of detecting the discharge positions at both parasitic capacitors is the same. That is, in the embodiments shown in FIG. 7(a) and FIG. 7(b), in the actual detection, the structure and position of the coupling plate 1 may be adjusted to make the capacitance value of the first parasitic capacitor 44 equal to the capacitance value of the second parasitic capacitor 45. In this way, no matter where the partial discharge occurs inside the device under test, the detection effect is the same.

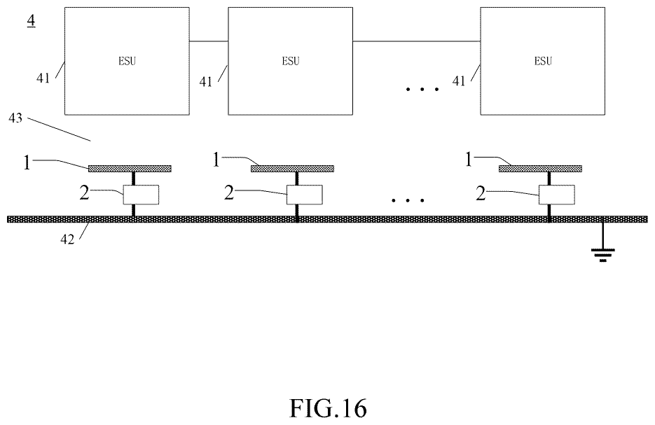

The coupling conductor 1 in some embodiments shown in the present disclosure may, in practical applications, be in a variety of structural forms such as a plate-like structure (e.g., the coupling plate 1 in the embodiments shown in FIGS. 7(a) and 7(b)), an L-shape structure, a U-shape structure, an arc-shaped structure, or other polyhedrons, etc. Correspondingly, in practical applications, the first conductor 41 and the second conductor 42 may also be in various structural forms such as the plate-like structure, the L-shaped structure, the U-shaped structure, the arc structure or other polyhedrons. The structures of the first conductor 41 and the second conductor 42 may be the same (both are hexahedral structures as shown in the embodiments of FIG. 7(a) and FIG. 7(b)), or may be different (the first conductor 41 is a hexahedral structure, while the second conductor 42 is a plate-like structure as shown in the embodiments of FIG. 16 to FIG. 19). The structure of the coupling conductor 1 changes with the structures of the first conductor 41 and the second conductor 42, and is adjusted and changed according to the distribution of the original parasitic capacitance. For example, when the first conductor 41 and the second conductor 42 are of a U-shaped structure, the coupling conductor 1 bends as the structures of the first conductor 41 and the second conductor 42 change, thereby forming a coupling conductor 1 of the same U-shaped structure. In addition, the coupling conductor 1 may also have a structure different from that of the first conductor 41 and the second conductor 42. For example, when the first conductor 41 and the second conductor 42 are of an arc-shaped structure, the coupling conductor 1 may be of a plate-like structure. Taking the device under test 4 in FIG. 7(a) and FIG. 7(b) as an example, the first conductor 41 is a high-voltage conductor inside the device under test 4, that is, the battery cell aluminum shell 41 (hexahedral structure), the second conductor 42 is the outer shell of the device under test 4, that is, the box shell 42 (hexahedral structure), and the coupling conductor 1 is the coupling plate (plate-like structure).

At least one of the first conductor 41, the second conductor 42, and the coupling conductor 1 in some of the embodiments shown in the present disclosure may, in practical applications, have a complete metal layer on any surface (such as the battery cell aluminum shell 41 in the embodiments of FIG. 7(a) and FIG. 7(b)), or have a hollow structure on some of the surfaces (such as a grounded shell 42 with heat dissipation ventilation holes, or a coupling conductor 1 designed to be an antenna-shaped, etc.).

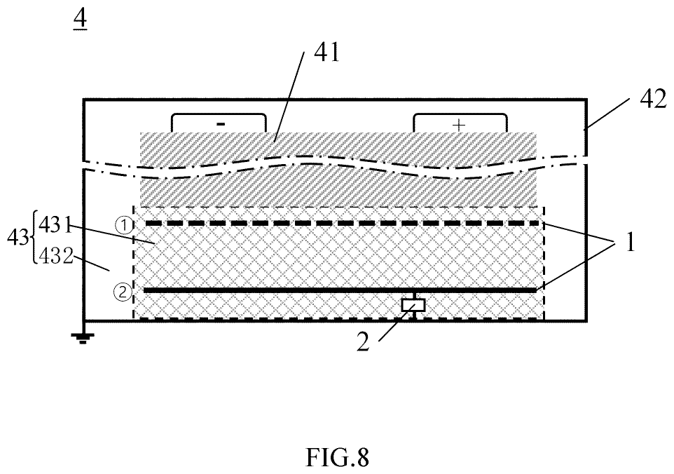

FIG. 8 shows a schematic diagram of an evaluation of the location where a coupling conductor 1 is mounted. Still taking the example where the insulation detection apparatus 100 of the present disclosure is applied to the energy storage battery 4, as shown in FIG. 8, when the coupling conductor 1 is adjacent to the battery cell aluminum shell 41, that is, the coupling conductor 1 is designed at position \textcircled{1}, since the battery cell aluminum shell 41 is a high-voltage conductor and corresponds to a high potential of the first conductor 41, and the signal acquisition unit 2 involves a low-voltage secondary circuit, it is necessary to design a complex insulation structure to avoid the influence of the high-voltage conductor on the signal acquisition unit 2, thereby increasing the insulation cost of the signal acquisition unit 2. When the coupling conductor 1 is adjacent to the box shell 42, that is, the coupling conductor 1 is designed at position \textcircled{2}, since the box shell 42 is grounded and corresponds to a low potential (zero potential) of the second conductor 42, there is no need to perform additional insulation design on the signal acquisition unit, and there is no need to give additional consideration to the problem of insulation and isolation, which saves costs. Through the above comparison between the designs, the coupling conductor 1 is designed to be located close to the box shell 42, so that the distance between the coupling conductor 1 and the first conductor 41 is greater than the distance between the coupling conductor 1 and the second conductor 42.

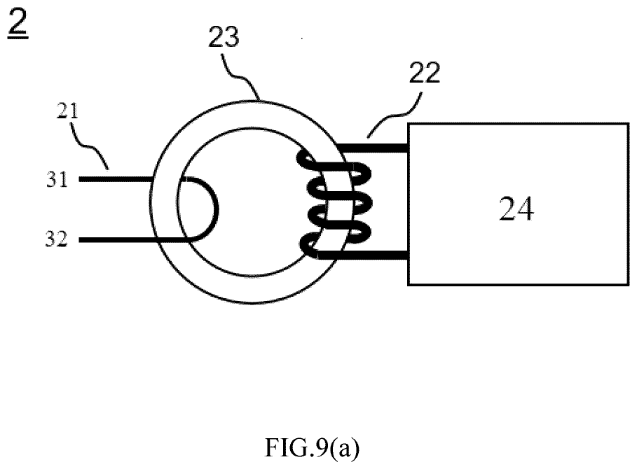

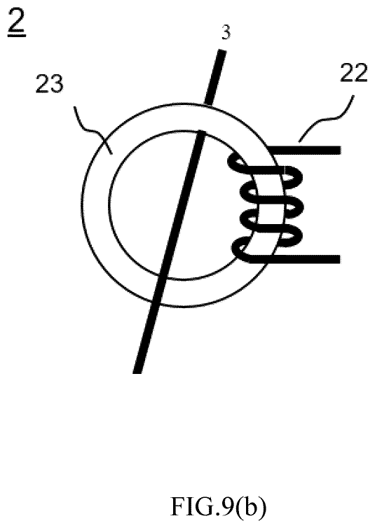

In some embodiments of the present disclosure, as shown in FIG. 3 and FIG. 9(a), the signal acquisition unit 2 is a current sensor, including a primary winding 21, a secondary winding 22 and a magnetic ring 23. The current sensor collects partial discharge signals by using the principle of electromagnetic induction, and has the ability to provide high isolation voltage between the primary winding 21 and the secondary winding 22. The lead 3 includes a first lead 31 and a second lead 32, where the first lead 31 and the second lead 32 are respectively electrically connected to the two ends of the primary winding 21 of the current sensor 2. When partial discharge occurs in the device 4 being detected, the generated high-frequency pulse current flows through the primary winding 21 and is transferred to the secondary winding 22.

Further, as shown in FIG. 9(a), which shows a schematic structural diagram of the signal acquisition apparatus in the embodiment of the present disclosure, the signal acquisition unit 2 further includes a signal processing unit 24, and the secondary winding 22 of the signal acquisition unit 2 may be electrically connected to the signal processing unit 24 to amplify, filter, and transmit the collected partial discharge signal to the system controller, etc.

Furthermore, in some embodiments of the present disclosure, as shown in FIG. 9(b), the difference from the embodiment shown in FIG. 9(a) is that the first lead 31 and the second lead 32 are combined into one lead 3, and the lead 3 also serves as the primary winding of the current sensor 2. The lead 3 passes through the magnetic ring 23, one end of which is electrically connected to the coupling conductor 1, and the other end of which is electrically connected to the first conductor 41 or the second conductor 42 in the device under test 4.

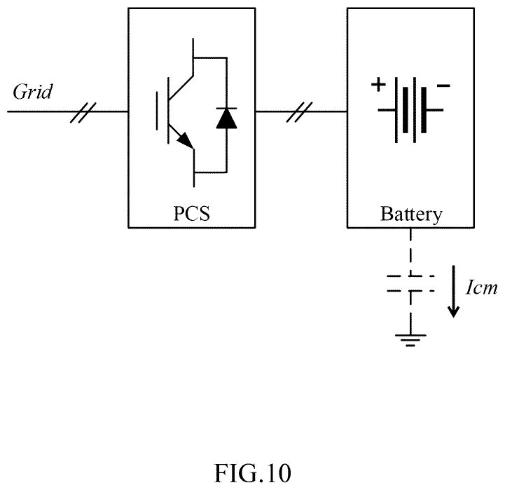

FIG. 10 shows a schematic diagram of the principle of generating common-mode interference current Icm. As shown in FIG. 10, in the energy storage system, there is an electrical connection between the battery and the power conversion system (PCS). When the switch state in the PCS is switched, the voltage at the DC bus transiently changes and discharges through the parasitic capacitance to earth thereby generating a common-mode interference current Icm. For partial discharge detection, the common-mode interference current Icm is an interference signal that may be superimposed with the high-frequency pulse signal collected by the signal acquisition unit 2. If the common-mode interference current signal cannot be suppressed or screened out, it will lead to a misjudgment.

In a system containing a power electronic switch with high-frequency action, in order to avoid interference from common-mode signals generated by the power electronic switch, the signal acquisition unit 2 may be controlled to collect the high-frequency pulse current signal flowing through the coupling capacitor in a time period that does not include the switch action moment. On the other hand, according to existing accident reports, energy storage accidents often occur when the battery is fully charged and in standby state. At this moment, the switch does not operate and common-mode interference source does not exist. In addition, topology design and control methods may also be utilized to achieve a zero common-mode system, which also directly avoids common-mode interference current. In this way, the collected high- frequency pulse current signal only contains the partial discharge signal, thereby achieving accurate judgment.

Since the common-mode interference signal comes from the periodic switching of the power electronic switch, the common-mode interference signal is a repetitive signal with a certain period. Meanwhile, the partial discharge signal is random and has no fixed period. Therefore, a frequency selection circuit may be designed to screen out the common-mode interference current.

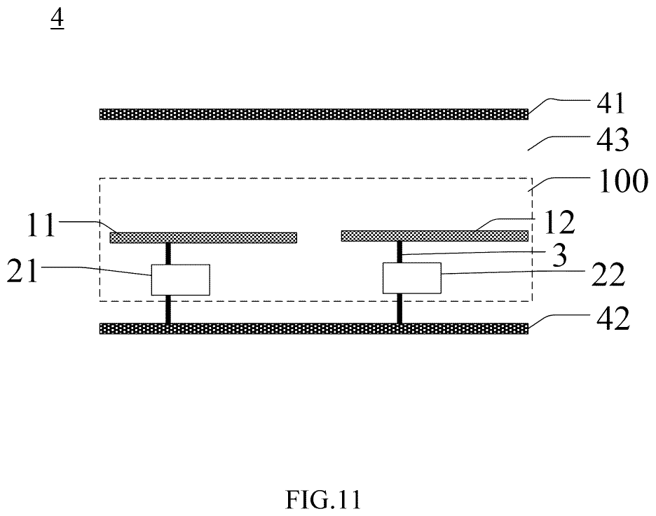

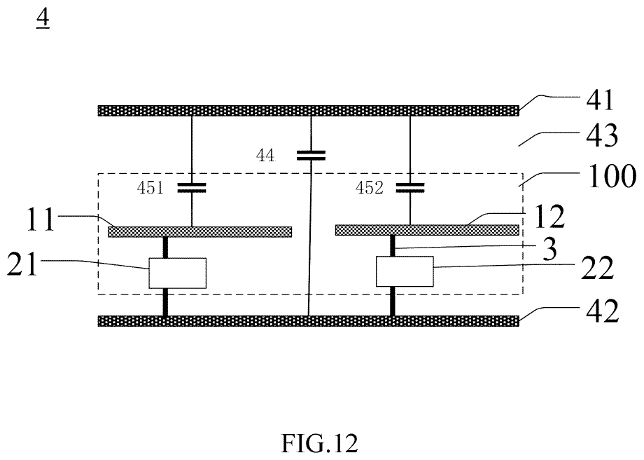

FIG. 11 shows a structural diagram of a phase-shift differential dual sensor in an embodiment of the present disclosure. FIG. 12 shows an equivalent diagram of the parasitic capacitance in FIG. 11. As shown in FIG. 11 and FIG. 12, the coupling conductor 1 includes a first coupling sub-conductor 11 and a second coupling sub-conductor 12; the first conductor 41, the insulating medium 43 provided between the first conductor 41 and the first coupling sub-conductor 11, and the first coupling sub-conductor 11 constitute a first parasitic sub-capacitor 451; the first conductor 41, the insulating medium 43 provided between the first conductor 41 and the second coupling sub-conductor 12, and the second coupling sub-conductor 12 constitute a second parasitic sub-capacitor 452; the capacitance values of the first parasitic sub-capacitor 451 and the second parasitic sub-capacitor 452 are the same; the signal acquisition unit 2 includes a first signal acquisition sub-unit 21 and a second signal acquisition sub-unit 22; the first signal acquisition sub-unit 21 is electrically connected between the first coupling sub-conductor 11 and the second conductor 42; and the second signal acquisition sub-unit 22 is electrically connected between the second coupling sub-conductor 12 and the second conductor 42.

The first parasitic sub-capacitor 451 and the second parasitic sub-capacitor 452 with the same capacitance value are formed, respectively, by using the first coupling sub-conductor 11 and the second coupling sub-conductor 12, and in conjunction with the first parasitic capacitance 44 formed by the first conductor 41, the insulating medium 43 between the first conductor 41 and the second conductor 42, and the second conductor 42, the detection of the partial discharge signal is realized. For example, the first parasitic capacitor 44 serves as the test capacitor C1, the first parasitic sub-capacitor 451 serves as a coupling capacitor C2 to form a first coupling branch, and the second parasitic sub-capacitor 452 also serves as the coupling capacitor C2 to form a second coupling branch. Both the first coupling branch and the second coupling branch are used to detect the partial discharge signal of the test capacitor C1. Alternatively, the first parasitic sub-capacitor 451 serves as the test capacitor C1, the first parasitic capacitor 44 serves as the coupling capacitor C2 to form the first coupling branch, and the second parasitic sub-capacitor 452 also serves as the coupling capacitor C2 to form the second coupling branch. Both the first coupling branch and the second coupling branch are used to detect the partial discharge signal of the test capacitor C1. Alternatively, the second parasitic sub-capacitor 452 serves as the test capacitor C1, the first parasitic capacitor 44 serves as the coupling capacitor C2 to form the first coupling branch, and the first parasitic sub-capacitor 451 also serves as the coupling capacitor C2 to form the second coupling branch. Both the first coupling branch and the second coupling branch are used to detect the partial discharge signal of the test capacitor C1.

In the embodiments, the first coupling sub-conductor 11 and the second coupling sub-conductor 12 have the same shape and size. By arranging the first coupling sub-conductor 11 and the second coupling sub-conductor 12 at the same height relative to the second conductor 42 inside the insulating medium 43, the same capacitance value of the first parasitic sub-capacitance 451 and the second parasitic sub-capacitance 452 is realized.

In the embodiments, the first signal acquisition sub-unit 21 outputs a first partial discharge detection result, and the second signal acquisition sub-unit 22 outputs a second partial discharge detection result; where the first partial discharge detection result and the second partial discharge detection result are staggered by one common-mode cycle and then subtracted to eliminate the common-mode signal.

The phase-shifted differential dual sensor of this embodiment, when suppressing common-mode interference signals, obtains the first parasitic sub-capacitor 451 and the second parasitic sub-capacitor 452 having the same capacitance value by setting the first coupling sub-conductor 11 and the second coupling sub-conductor 12 having the same shape and size, so that the common-mode signals in the first partial discharge detection result and the second partial discharge detection result are the same. Since the common-mode signal has a fixed period, while the partial discharge signal is random, the common-mode signal will be eliminated and the partial discharge signal will be retained by subtracting the first partial discharge detection result from the second partial discharge detection result after staggering them by one common-mode period.

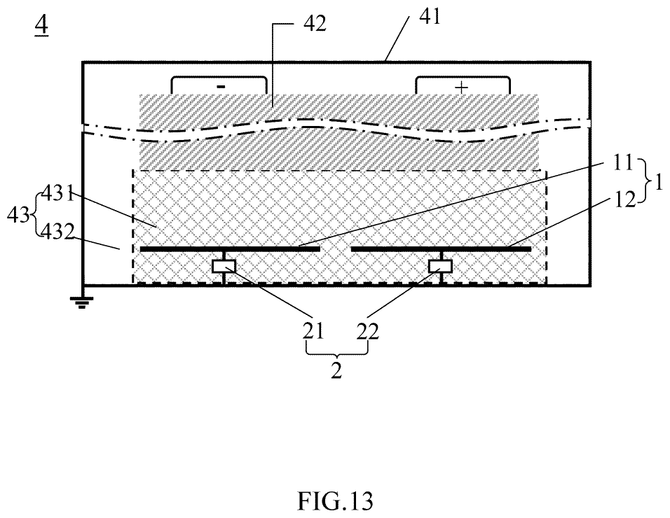

FIG. 13 shows an application structural diagram of the phase-shift differential dual sensor in an embodiment of the present disclosure. Still taking the example where the insulation detection apparatus 100 of the present disclosure is applied to the energy storage battery 4, as shown in FIG. 13, the device under test 4 is the energy storage battery 4, and the energy storage battery 4 includes: the battery cell, the battery cell aluminum shell 41, the PU glue 431, the insulating gas 432 and the box shell 42. The battery cell and the battery cell aluminum shell 41 are electrically connected, thus the battery cell and the battery cell aluminum shell 41 have the same potential. The battery cell aluminum shell 41 serves as the first conductor 41 herein. The PU glue 431 serves as the insulating medium 43 to insulate and isolate the mounting surface of the battery cell aluminum shell 41 from the box shell 42, and the insulating gas 432 also serves as the insulating medium 43 to insulate and isolate the other surfaces of the battery cell aluminum shell 41 from the box shell 42. The box shell 42 is grounded as the second conductor 42, and there is a potential difference between the box shell 42 and the battery core aluminum shell 41. A first coupling plate 11 serves as the first coupling sub-conductor 11, and a second coupling plate 12 serves as the second coupling sub-conductor 12. The first coupling plate 11 and the second coupling plate 12 have the same shape and size, and are arranged at the same height relative to the box shell 42 inside the PU glue 431. The first coupling plate 11 is electrically connected to one end of the first signal acquisition sub-unit 21, and the other end of the first signal acquisition sub-unit 21 is electrically connected to the box shell 42 for acquiring the partial discharge signal and outputting a first detection result of the high- frequency pulse current of the partial discharge. The second coupling plate 12 is electrically connected to one end of the second signal acquisition subunit 22, and the other end of the second signal acquisition sub-unit 22 is electrically connected to the box shell 42 for collecting the high-frequency pulse current signal of partial discharge and outputting the second partial discharge detection result. The common-mode signal can be eliminated by subtracting the first partial discharge detection result from the second partial discharge detection result after staggering them by one common-mode cycle, and the remaining is the partial discharge signal.

In the embodiments, the above coupling conductor 1 is a combination of at least one or more of the following: a metallized film, a thin layer with sprayed metal, a copper clad laminate, and a printed circuit board. The metallized film may be made to be micron thick, which is a mature process, and the metallized film is easy to be integrated into the box shell 42. The sprayed metal may be obtained by providing the insulating medium 43 on one side of the box shell 42 and spraying a metal layer on the side of the insulating medium 43 away from the box shell 42. The thin layer with sprayed metal may achieve micron thickness and easily integrated into the box shell 42. The copper clad laminate and printed circuit board may achieve millimeter thickness and may be highly integrated with other electronic component(s) and/or device(s) used for signal acquisition and processing.

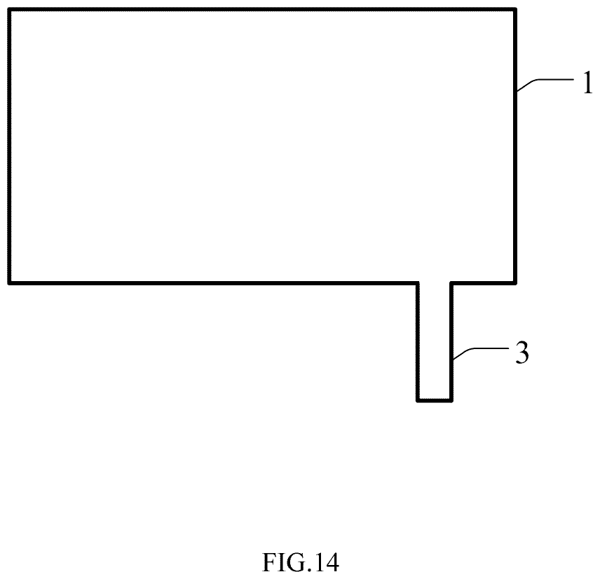

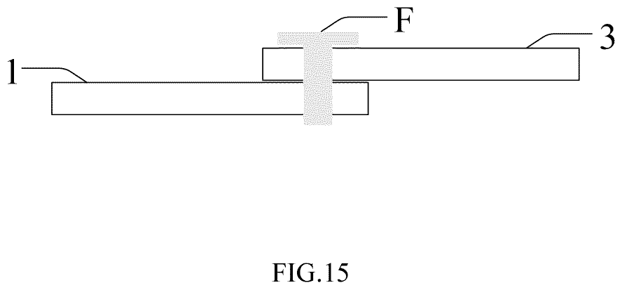

FIG. 14 shows a structural diagram of an integrated design of the lead 3. As shown in FIG. 14, in the embodiment, the lead 3 and the coupling conductor 1 are integrally formed, thereby realizing the integrated design of the lead 3 and reducing contact resistance. In another embodiment, FIG. 15 shows a structural diagram of a design of a discrete lead 3. As shown in FIG. 15, the lead 3 and the coupling conductor 1 may also be designed separately, and the coupling conductor 1 and the lead 3 are connected by a fastener F. The design of the discrete lead facilitates installation and disassembly, but the connection via the fastener F introduces additional contact impedance that affects detection sensitivity.

The insulation detection apparatus of the embodiments of the present disclosure may be applied to battery assemblies, high-voltage electrical systems and chassis of new energy vehicles, and energy storage systems. The energy storage system may be a low-voltage energy storage system, a medium-voltage energy storage system, or a high-voltage energy storage system. The insulation detection apparatus may also be applied in smart grids, where partial discharge detection can be implemented by using the insulation detection apparatus to provide support for digital grids, for example, in high-voltage electrical apparatuses such as transformers, cables and switch cabinets.

The embodiments of the present disclosure further provide an energy storage apparatus 4, including: the aforementioned insulation detection apparatus 100; an energy storage unit (ESU) and a mounting structure 42, the energy storage apparatus 4 and the mounting structure 42 serve as the device under test 4, and are used to be electrically connected to the insulation detection apparatus 100. The energy storage apparatus 4 includes at least the first conductor 41 and the second conductor 42 with different potentials. For example, the energy storage apparatus 4 includes an energy storage unit (ESU), the insulating medium 43 and the mounting structure 42, where the energy storage unit (ESU) contains a battery and related components with a high potential, thus the shell 41 of the energy storage unit (ESU) may serve as the first conductor 41. The mounting structure 42 is connected to the earth, has a low potential (zero potential) and serves as the second conductor 42. The insulating medium 43 is provided between the shell 41 and the mounting structure 42 to insulate and isolate the shell 41 from the mounting structure 42. In some embodiments of the present disclosure, the mounting structure 42 may be a plate-shaped structure, such as a container floor. In some other embodiments of the present disclosure, the mounting structure 42 may also be an empty box-like structure, and each energy storage unit (ESU) at least partially disposed within the mounting structure 42.

In some embodiments of the present disclosure, the energy storage apparatus 4 includes N energy storage units (ESUs) connected in series, where N is a positive integer greater than or equal to 2. That is, the energy storage apparatus 4 includes two or more energy storage units (ESUs) connected in series.

FIG. 16 shows a first structural schematic diagram of the energy storage apparatus 4. As shown in FIG. 16, in the embodiment, the energy storage apparatus 4 includes N coupling conductors 1 and N signal acquisition units 2, where the N coupling conductors 1 are independent of each other, and the N signal acquisition units 2 are electrically connected to the corresponding coupling conductors 1 and the mounting structure 42, respectively. In this embodiment, the configuration relationship between the insulation detection apparatus 100 and the energy storage unit (ESU) is 1:1, and each energy storage unit (ESU) is configured with one insulation detection apparatus 100, that is, each energy storage unit (ESU) is configured with one coupling conductor 1 and one signal acquisition unit 2. In the energy storage apparatus 4, the coupling conductor 1 is arranged in the insulating medium 43 between the first conductor 41 and the second conductor 42 of the energy storage apparatus 4, and the signal acquisition unit 2 is electrically connected between the coupling conductor 1 and the second conductor 42. By configuring a plurality of signal acquisition units 2, rapid localization of partial discharges can be achieved to accurately find the energy storage unit (ESU) in which the partial discharge has occurred.

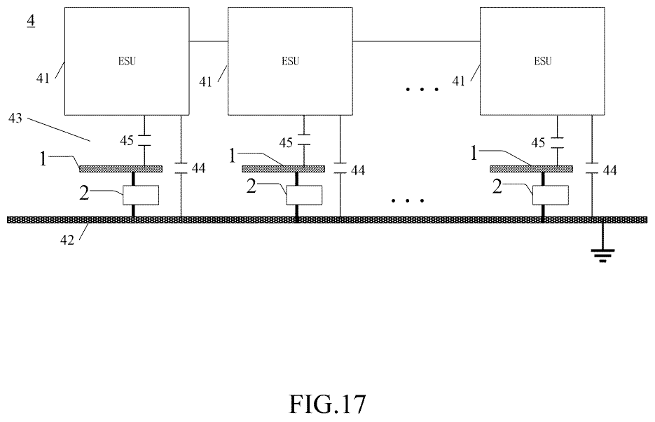

FIG. 17 shows an equivalent diagram of the parasitic capacitance in FIG. 16. As shown in FIG. 17, the shell 41 of the energy storage unit (ESU), the insulating medium 43 provided between the shell 41 of the energy storage unit (ESU) and the mounting structure 42, and the mounting structure 42 constitute the first parasitic capacitor 44; the shell 41 of the energy storage unit (ESU), the insulating medium 43 provided between the shell 41 of the energy storage unit (ESU) and the coupling conductor 1, and the coupling conductor 1 constitute a second parasitic capacitor 45; one of the first parasitic capacitor 44 and the second parasitic capacitor 45 is the test capacitor, and the other is the coupling capacitor; the signal acquisition unit 2 is electrically connected between the coupling conductor 1 and the mounting structure 42; the signal acquisition unit 2, the test capacitor and the coupling capacitor form the insulation detection loop; and the signal acquisition unit 2 collects the partial discharge signal flowing through the insulation detection loop and outputs the partial discharge detection result of the test capacitor.

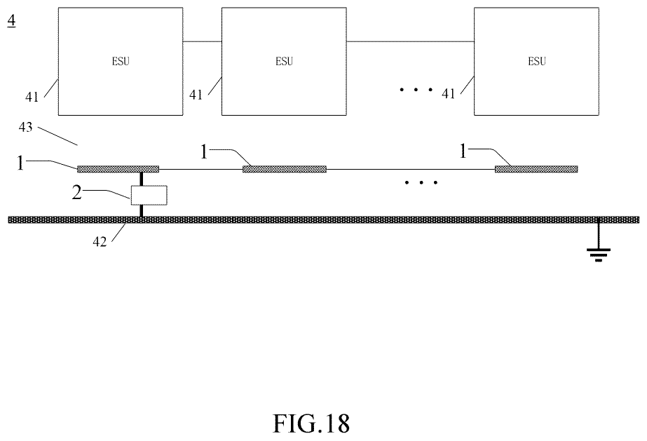

FIG. 18 shows a second structural schematic diagram of the energy storage apparatus 4. As shown in FIG. 18, in the embodiment, the energy storage apparatus 4 includes N coupling conductors 1 connected in series and one signal acquisition unit 2. The signal acquisition unit 2, one of the N coupling conductors 1, and the mounting structure 42 are electrically connected. In this embodiment, the configuration relationship between the energy storage unit (ESU) and the coupling conductor 1 is 1:1, each energy storage unit is configured with one coupling conductor, and multiple coupling conductors 1 are connected in series with a same potential. In the energy storage apparatus 4, the coupling conductor 1 is provided in the insulating medium 43 between the first conductor 41 and the second conductor 42 of the energy storage apparatus 4, one signal acquisition unit 2 is electrically connected to any one of the plurality of coupling conductors 1, and the one signal acquisition unit 2 is electrically connected between any one of the plurality of coupling conductors 1 with the same potential and the second conductor 42. The coupling conductors 1 are provided to be multiple, and the size of each coupling conductor 1 is relatively small, which is convenient for processing, thus, partial discharge monitoring of ultra-large-scale energy storage systems can be realized.

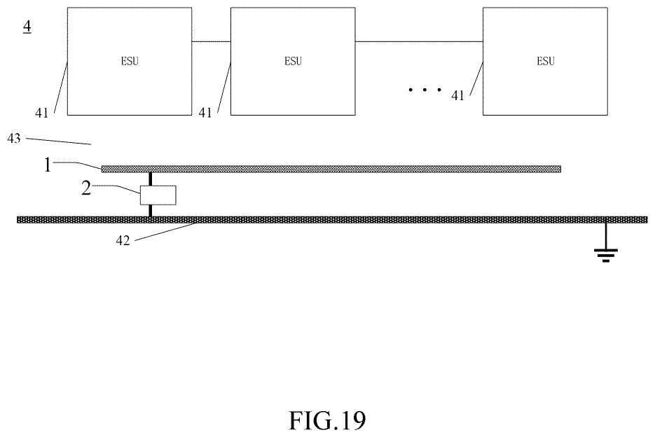

FIG. 19 shows a third structural schematic diagram of the energy storage apparatus 4. As shown in FIG. 19, in the embodiment, the energy storage apparatus 4 includes one coupling conductor 1 and one signal acquisition unit 2, where the coupling conductor 1 at least covers at least a portion of an area of each of the N energy storage units (ESUs), and the signal acquisition unit 2, the coupling conductor 1 and the mounting structure 42 are electrically connected. In this embodiment, there are multiple energy storage units (ESUs), and there is only one coupling conductor and one signal acquisition unit. The coupling conductor 1 is integrally designed and may cover all of the energy storage units (ESUs), and one signal acquisition unit 2 is electrically connected between the coupling conductor 1 and the second conductor 42. The integrated coupling conductor 1 has a simple structure and is suitable for partial discharge detection in large and medium-scale energy storage systems.

The configuration relationship between the insulation detection apparatus 100 and the energy storage unit (ESU) of this embodiment may be 1 to 1, where each energy storage unit (ESU) is configured with an independent coupling conductor 1, and an independent partial discharge signal acquisition unit 2 is connected in series between the coupling conductor 1 and the second conductor 42. The configuration relationship between the insulation detection apparatus 100 and the energy storage unit (ESU) may also be one-to-many, where multiple separate coupling conductors 1 are installed, and the coupling conductors 1 are electrically connected to a same potential; and the partial discharge signal acquisition unit 2 is connected in series between one of the coupling conductors 1 and the second conductor 42. Alternatively, an integrated coupling conductor 1 is placed to completely cover the shell 41 of the certain number of energy storage units (ESUs), and the partial discharge signal acquisition unit 2 is connected in series between the coupling conductor 1 and the second conductor 42.

In the medium and high voltage energy storage system, the energy storage unit (ESU) has a high voltage insulation requirement to the ground, and the high voltage coupling capacitor device without partial discharge is costly and bulky. Therefore, the application of the insulation detection apparatus of this embodiment has the advantages of simple structure and low cost. In addition, each insulation detection apparatus is equipped with a corresponding positioning apparatus to achieve accurate positioning of partial discharge and intelligent networking.

In the embodiments of the present disclosure, the insulating medium 43 in the device under test 4 may be one or more combinations of insulating gas, solid, and liquid. Furthermore, the insulating medium 43 between the first conductor 41 and the second conductor 42 and the insulating medium 43 between the first conductor 41 and the coupling conductor 1 may be of the same material and form of composition, or may be of different material and form of composition. For example, in a battery pack, the place for installing the battery cell may be insulated by a combination of PU glue 431 and an insulating film, and other places may be insulated by a combination of insulating air 432 and the insulating film. For another example, in the medium voltage energy storage apparatus, the energy storage unit (ESU) and the mounting structure 42 may be insulated by a combination of air and a supporting insulator.

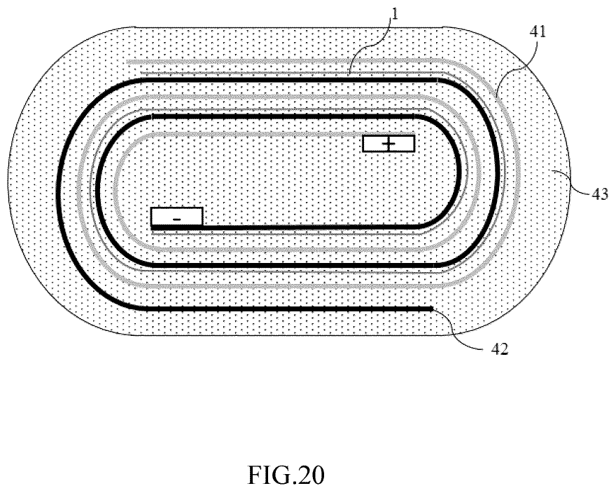

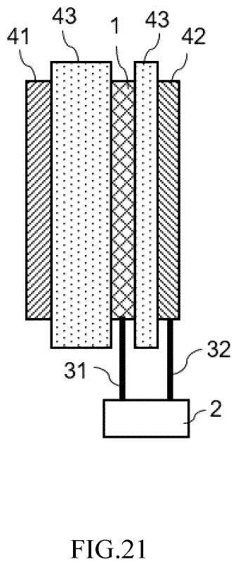

FIG. 20 shows a schematic structural diagram of the device under test in an embodiment of the present disclosure. FIG. 21 shows a side view schematic diagram of the signal acquisition apparatus in the embodiment of the present disclosure applied to the device under test shown in FIG. 20. The device under test 4 is a battery cell, and the battery cell 4 includes a positive electrode 41, a negative electrode and a shell 42, and an insulating separator 43. Here, the positive electrode 41 serves as the first conductor 41, the negative electrode 42 serves as the second conductor 42, a potential difference exists between the negative electrode 42 and the positive electrode 41, and the insulating separator 43 serves as the insulating medium 43 to insulate and isolate the positive electrode 41 from the negative electrode 42. The coupling sheet 1 serves as the coupling conductor 1 and is disposed in the insulating separator between the positive electrode 41 and the negative electrode 42. The area of the coupling sheet 1 is smaller than the area of the positive electrode 41 and the negative electrode 42. The coupling sheet 1 is electrically connected to one end of the signal acquisition unit 2 through a lead 31, and the other end of the signal acquisition unit 2 is electrically connected to the negative electrode 42 through a lead 32, for collecting pulse current signals of partial discharge. The positive electrode 41, the insulating separator 43 between the positive electrode 41 and the negative electrode 42, and the negative electrode 42 constitute a parasitic capacitor C, which is equivalent to the first parasitic capacitor 44 mentioned above; the positive electrode 41, the insulating separator 43 between the positive electrode 41 and the coupling sheet 1, and the coupling sheet 1 constitute a parasitic capacitor C′, which is equivalent to the second parasitic capacitor 45 mentioned above; and the parasitic capacitance C and parasitic capacitance C′ are mutually the test capacitance and coupling capacitance. That is, when the parasitic capacitance C is the test capacitance, the parasitic capacitance C′ is the coupling capacitance; when the parasitic capacitance C′ is the test capacitance, the parasitic capacitance C is the coupling capacitance. In the embodiments shown in FIG. 20 and FIG. 21, when there is a partial insulation failure in the insulating medium 43 disposed between the positive electrode 41 and the coupling sheet 1, for example, a partial high field strength distortion within a bubble defect causes a partial discharge, the parasitic capacitor C′ serves as the test capacitor, the parasitic capacitor C serves as the coupling capacitor, and the signal acquisition unit 2 collects the pulse current signal of the partial discharge and outputs the partial discharge detection result of the test capacitor. When the insulating medium 43 provided between the positive electrode 41 and the negative electrode 42 has a partial insulation failure and generates a partial discharge, the parasitic capacitor C serves as the test capacitor; the parasitic capacitor C′ serves as the coupling capacitor, and the signal acquisition unit 2 collects the pulse current signal of the partial discharge and outputs the partial discharge detection result of the test capacitor.

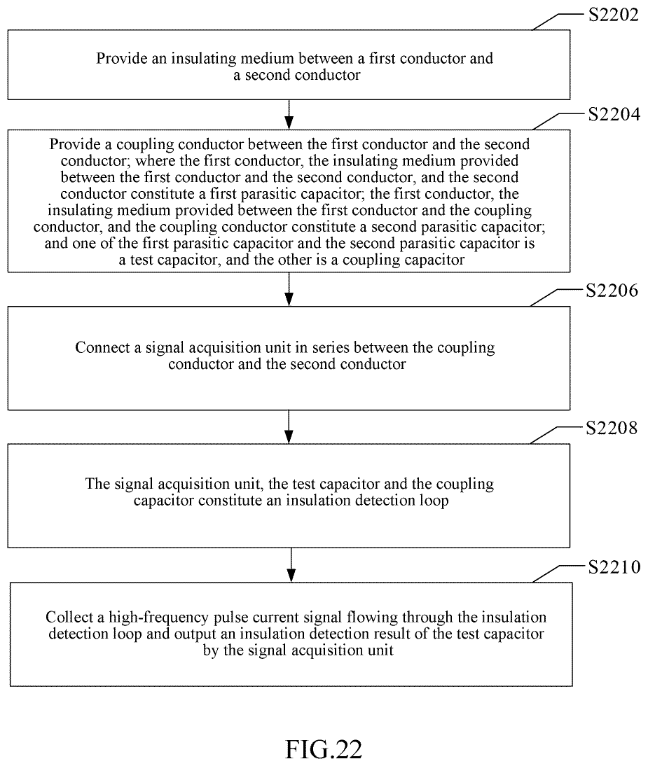

FIG. 22 shows an insulation detection method according to an embodiment of the present disclosure. As shown in FIG. 22, the present disclosure further provides an insulation detection method, where the method includes the following steps.

In step S2202: an insulating medium is provided between a first conductor and a second conductor.

In step S2204: a coupling conductor is provided between the first conductor and the second conductor; where the first conductor, the insulating medium provided between the first conductor and the second conductor, and the second conductor constitute a first parasitic capacitor; the first conductor, the insulating medium provided between the first conductor and the coupling conductor, and the coupling conductor constitute a second parasitic capacitor; one of the first parasitic capacitor and the second parasitic capacitor is a test capacitor, and the other is a coupling capacitor.

In step S2206: a signal acquisition unit is electrically connected between the coupling conductor and the second conductor.

In step S2208: the signal acquisition unit, the test capacitor and the coupling capacitor constitute an insulation detection loop.

In step S2210: a high-frequency pulse current signal flowing through the insulation detection loop is acquired by the signal acquisition unit, and an insulation detection result of the test capacitor is outputted.

The insulation detection apparatus and method, and the applied energy storage apparatus provided by the embodiments of the present disclosure have a high detection sensitivity, and can detect the weak discharge information at the initial stage of partial discharge and warn in advance, thereby leaving sufficient time for protection action of the system. Only the coupling conductor is used to construct the coupling capacitor, without the need to install the non-partial discharge medium and high voltage capacitor which are costly, so that the cost thereof is low. The structure of the coupling conductor may be designed to be flat for easy integration, so that the size thereof is small. The original parasitic capacitance of the device under test is divided into two by the coupling conductor, which will not increase the parasitic capacitance of the system and prevent the growth of common-mode interference current, so that the interference to the system is small. The interference of common-mode interference current signals can be screened out through control, frequency selection, and phase-shift differential dual sensor technologies, thus achieving strong anti-interference capabilities. The detection range thereof is wide and they can effectively detect inherent defects in insulating components, deterioration of performance of insulating components due to harsh operating conditions, insulating defects caused by design/production/assembly processes, and insulation failures such as component short circuits caused by liquid leakage. They have high value-added benefits and can be applied to battery components, electric vehicles, energy storage systems, smart grids and other fields, with great potential of market scale.

Furthermore, although various steps of the methods in the present disclosure are depicted in the drawings in a specific order, it does not require or imply that the steps must be performed in that specific order, or that all of the illustrated steps must be performed to achieve the desired results. Additionally or alternatively, certain steps may be omitted, multiple steps may be combined into one step for execution, and/or one step may be decomposed into multiple steps for execution, etc.

Other implementation manners of the present disclosure will be readily apparent to those skilled in the art upon consideration of the specification and practice of the present disclosure disclosed herein. The present disclosure is intended to cover any variations, uses, or adaptations of the present disclosure that follow the general principles of the present disclosure and include common knowledge or customary technical means in the technical field that are not disclosed in the present disclosure. The specification and embodiments are to be considered as exemplary only, and the true scope and spirit of the present disclosure are indicated by the appended claims.

What is claimed is:

1. An insulation detection apparatus, comprising: a coupling conductor and a signal acquisition unit, wherein the coupling conductor and the signal acquisition unit are electrically connected, the coupling conductor and the signal acquisition unit are configured to form an insulation detection loop with a device under test, and the signal acquisition unit is further configured to detect an electrical signal in the insulation detection loop.

2. The insulation detection apparatus according to claim 1, wherein the coupling conductor and the signal acquisition unit are electrically connected via a lead.

3. The insulation detection apparatus according to claim 2, wherein the device under test comprises a first conductor and a second conductor, the first conductor and the second conductor have different potentials, and an insulating medium is provided between the first conductor and the second conductor;
wherein the coupling conductor is provided between the first conductor and the second conductor, and the signal acquisition unit is further electrically connected to the first conductor or the second conductor via the lead to form the insulation detection loop.

4. The insulation detection apparatus according to claim 3, wherein the lead and the coupling conductor are integrally formed.

5. The insulation detection apparatus according to claim 3, wherein the electrical signal is a partial discharge signal in the device under test.

6. The insulation detection apparatus according to claim 5, wherein the first conductor, the insulating medium provided between the first conductor and the second conductor, and the second conductor constitute a first parasitic capacitor; the first conductor, the insulating medium provided between the first conductor and the coupling conductor, and the coupling conductor constitute a second parasitic capacitor; one of the first parasitic capacitor and the second parasitic capacitor is a test capacitor, and the other is a coupling capacitor; and the signal acquisition unit is electrically connected between the coupling conductor and the second conductor;
wherein the signal acquisition unit, the test capacitor and the coupling capacitor constitute the insulation detection loop; and the signal acquisition unit acquires the partial discharge signal flowing through the insulation detection loop and outputs a partial discharge detection result of the test capacitor.

7. The insulation detection apparatus according to claim 6, wherein the partial discharge signal is a high-frequency pulse current signal.

8. The insulation detection apparatus according to claim 6, wherein the first conductor, the second conductor and the coupling conductor are in a plate-like structure, an L-shaped structure, a U-shaped structure, an arc-shaped structure or a polyhedron structure.

9. The insulation detection apparatus according to claim 6, wherein any surface of at least one of the first conductor, the second conductor and the coupling conductor is a hollow structure.

10. The insulation detection apparatus according to claim 6, wherein the first conductor is a high-voltage conductor inside the device under test, and the second conductor is a shell of the device under test.

11. The insulation detection apparatus according to claim 6, wherein a distance between the coupling conductor and the first conductor is greater than a distance between the coupling conductor and the second conductor.

12. The insulation detection apparatus according to claim 6, wherein a capacitance value of the first parasitic capacitor is equal to a capacitance value of the second parasitic capacitor.

13. The insulation detection apparatus according to claim 5, wherein the insulating medium between the first conductor and the second conductor is a combination of one or more of: gas, solid, and insulating liquid; and the insulating medium between the first conductor and the coupling conductor is a combination of one or more of: gas, solid, and insulating liquid.

14. The insulation detection apparatus according to claim 1, wherein the coupling conductor is a combination of at least one or more of: a metallized film, a thin layer with sprayed metal, a copper clad laminate, and a printed circuit board.

15. The insulation detection apparatus according to claim 3, wherein the signal acquisition unit is a current sensor, the current sensor comprises a magnetic ring, a primary winding and a secondary winding, the lead comprises a first lead and a second lead, one end of the first lead and one end of the second lead are respectively electrically connected to two ends of the primary winding, and the other end of the first lead and the other end of the second lead are respectively electrically connected to the coupling conductor and the first conductor or the second conductor in the device under test.

16. The insulation detection apparatus according to claim 3, wherein the signal acquisition unit is a current sensor, the current sensor comprises a magnetic ring, a primary winding and a secondary winding, the lead is further configured as the primary winding, the lead passes through the magnetic ring, one end of the lead is electrically connected to the coupling conductor, and the other end of the lead is electrically connected to the first conductor or the second conductor in the device under test.

17. An energy storage apparatus, comprising: an insulation detection apparatus, comprising: a coupling conductor and a signal acquisition unit, wherein the coupling conductor and the signal acquisition unit are electrically connected, the coupling conductor and the signal acquisition unit are configured to form an insulation detection loop with a device under test, and the signal acquisition unit is further configured to detect an electrical signal in the insulation detection loop;
an energy storage unit and a mounting structure, wherein the energy storage unit and the mounting structure serve as the device under test; and the energy storage unit or the mounting structure is configured to be electrically connected to the insulation detection apparatus.

18. The energy storage apparatus according to claim 17, wherein the energy storage apparatus comprises N energy storage units connected in series, wherein N is a positive integer greater than or equal to 2.

19. The energy storage apparatus according to claim 18, wherein the energy storage apparatus comprises N coupling conductors and N signal acquisition units, wherein the N coupling conductors are independent of each other, and the N signal acquisition units are electrically connected to corresponding coupling conductors and the mounting structure, respectively.

20. The energy storage apparatus according to claim 18, wherein the energy storage apparatus comprises N coupling conductors connected in series and one signal acquisition unit, and the signal acquisition unit, one of the N coupling conductors and the mounting structure are electrically connected.

21. The energy storage apparatus according to claim 18, wherein the energy storage apparatus comprises one coupling conductor and one signal acquisition unit, the coupling conductor at least covers at least a portion of an area of each of the N energy storage units, and the signal acquisition unit, the coupling conductor and the mounting structure are electrically connected.

22. An insulation detection method, comprising:
providing an insulating medium between a first conductor and a second conductor;
providing a coupling conductor between the first conductor and the second conductor; wherein the first conductor, the insulating medium provided between the first conductor and the second conductor, and the second conductor constitute a first parasitic capacitor; the first conductor, the insulating medium provided between the first conductor and the coupling conductor, and the coupling conductor constitute a second parasitic capacitor; one of the first parasitic capacitor and the second parasitic capacitor is a test capacitor, and the other is a coupling capacitor;
electrically connecting a signal acquisition unit between the coupling conductor and the second conductor;
constituting an insulation detection loop by the signal acquisition unit, the test capacitor and the coupling capacitor; and
acquiring a high-frequency pulse current signal flowing through the insulation detection loop by the signal acquisition unit, and outputting an insulation detection result of the test capacitor.

23. The insulation detection method according to claim 22, wherein a time period of acquiring the high-frequency pulse current signal flowing through the coupling capacitor does not comprise a moment of a switching action to eliminate a common-mode signal generated by the switching action.

24. The insulation detection method according to claim 22, wherein
the coupling conductor comprises a first coupling sub-conductor and a second coupling sub-conductor;
wherein the first conductor, the insulating medium provided between the first conductor and the first coupling sub-conductor, and the first coupling sub-conductor constitute a first parasitic sub-capacitor; the first conductor, the insulating medium provided between the first conductor and the second coupling sub-conductor, and the second coupling sub-conductor constitute a second parasitic sub-capacitor; and the first parasitic sub-capacitor and the second parasitic sub-capacitor have a same capacitance value;
wherein the signal acquisition unit comprises a first signal acquisition sub-unit and a second signal acquisition sub-unit;
wherein the first signal acquisition sub-unit is electrically connected between the first coupling sub-conductor and the second conductor; and the second signal acquisition sub-unit is electrically connected between the second coupling sub-conductor and the second conductor.

25. The insulation detection method according to claim 24, wherein the first coupling sub-conductor has a same shape and size as the second coupling sub-conductor.

26. The insulation detection method according to claim 24, wherein the first signal acquisition sub-unit outputs a first partial discharge detection result, and the second signal acquisition sub-unit outputs a second partial discharge detection result;
wherein the first partial discharge detection result and the second partial discharge detection result are staggered by one common-mode cycle and then subtracted to eliminate a common-mode signal.
